(19) United States
(12) Patent Application Publication
(10) Pub. No.: US 2025/0318337 A1
(43) Pub. Date: Oct. 9, 2025

(54) HOUSING AND LEADFRAME UNIT

(71) Applicant: ams-OSRAM International GmbH, Regensburg (DE)

(72) Inventor: Karlheinz Arndt, Bad Abbach (DE)

(21) Appl. No.: 18/865,152

(22) PCT Filed: May 5, 2023
(86) PCT No.: PCT/EP2023/061968

§ 371 Date: Nov. 12, 2024

(30) Foreign Application Priority Data
May 19, 2022 (DE) 102022112609.9

(51) Int. Cl. H10H 20/857; H10H 20/85

(52) U.S. Cl. CPC H10H 20/857; H10H 20/8506

(57) ABSTRACT

In an embodiment a housing includes a first leadframe part, a second leadframe part and a housing body mechanically connecting the first and second leadframe parts to one another, wherein the first leadframe part has a mounting region configured for attaching a semiconductor chip and/or for attaching an electrical connection, and an edge region at a lateral edge of the housing, wherein the first leadframe part has a trench between the mounting region and the edge region, wherein the trench is located on an outer side of the first leadframe part and the outer side is configured for mounting the housing, wherein the mounting region and the edge region extend as far as the outer side, wherein the housing body forms a first cavity and, in the first cavity, an inner side of the first leadframe part, which is configured for mounting the semiconductor chip, is free from the housing body, wherein the edge region is at least partially covered by a cavity wall of the first cavity, as seen in plan view of the inner side, and wherein, as seen in plan view of the inner side, all ends of the trench lie within the first cavity.

### CROSS-REFERENCE TO RELATED APPLICATIONS

This patent application is a national phase filing under section 371 of PCT/EP2023/061968, filed May 5, 2023, which claims the priority of German patent application 102022112609.9, filed May 19, 2022, each of which is incorporated herein by reference in its entirety.

### TECHNICAL FIELD

A housing for an optoelectronic semiconductor chip and a leadframe unit therefor are provided.

### SUMMARY

Embodiments provide a housing that is resistant to thermal loads.

According to at least one embodiment, the housing is provided for at least one optoelectronic semiconductor chip. The semiconductor chip or semiconductor chips are, for example, light-emitting diode chips, or LED chips for short, and/or laser diode chips, or LD chips for short. Several different types of optoelectronic semiconductor chips can be combined in the housing, for example, optoelectronic semiconductor chips for generating different colors of light.

According to at least one embodiment, the housing comprises a first leadframe part and a second leadframe part. Additional leadframe parts may be present. The term leadframe part refers in particular to metallic bodies which are, for example, stamped and/or etched and/or cut from a sheet metal. All leadframe parts are preferably made of the same base material, in particular a copper sheet or a copper foil. The leadframe parts can be provided with at least one metallic coating which, however, is preferably significantly thinner than the base material.

According to at least one embodiment, the housing comprises a housing body. The housing body is made of at least one electrically insulating material and is based, for example, on a plastic. The housing body may be based on an epoxy or silicone. It is possible that the housing body contains additives, such as particles or fibers to adapt thermal expansion or to improve mechanical stability. The housing body is preferably opaque.

According to at least one embodiment, the housing body mechanically connects the first and second leadframe parts and optional further leadframe parts to each other. In other words, without the housing body, the leadframe parts would not be mechanically stable relative to one another. For example, the housing body partially or completely covers the side surfaces of the leadframe parts, at least within the housing body. In the lateral direction, for example, the leadframe parts are only exposed from the housing body on outer side walls of the housing.

According to at least one embodiment, the first leadframe part has a mounting region for attaching a semiconductor chip and/or for attaching an electrical connecting means. Said semiconductor chip is in particular the at least one optoelectronic semiconductor chip, but the semiconductor chip can also be another type of semiconductor chip, for example, a control chip for the optoelectronic semiconductor chip or a protective chip, for example to protect against damage caused by electrostatic discharge, or ESD for short. In the mounting region, the first leadframe part preferably has its full thickness.

In the same way, the second leadframe part or optional further leadframe parts can also have a mounting region.

According to at least one embodiment, the first leadframe part has an edge region. The edge region is preferably located on a lateral edge of the housing. In other words, the edge region can border on the outer side walls of the housing. The edge region preferably also has the full thickness of the first leadframe part, in particular with the exception of a solder control point, which can be completely surrounded by an area of the edge region with full thickness in the direction towards the housing body. The solder control point is preferably accessible from the outer side walls.

The mounting region and the edge region can have the same full thickness.

According to at least one embodiment, the first leadframe part has a trench. The trench is located between the mounting region and the edge region. In other words, it is possible that the trench defines a subdivision between the mounting region and the edge region. The mounting region is then located on one longitudinal side of the trench and the edge region on an opposite longitudinal side. In the area of the trench, the first leadframe part is thinner than in the mounting region and than in the edge region, leaving out a possible solder control point.

According to at least one embodiment, the trench is located on an outer side of the first leadframe part. In this case, the outer side is configured for mounting the housing. In particular, the outer side is opposite an inner side, which is provided for the at least one optoelectronic semiconductor chip. For example, the outer side is set up for surface mounting, or SMT for short, of the housing. The trench can therefore be understood as a depression in the first leadframe part, which extends from the outer side into the base material of the first leadframe part towards the inner side, but does not reach the inner side. The trench is therefore not a hole through the first leadframe part.

According to at least one embodiment, the mounting region and the edge region extend to the outer side. This means that the mounting region and the edge region are sub-regions of the outer side.

In at least one embodiment, the housing is provided for an optoelectronic semiconductor chip and comprises
a first leadframe part and a second leadframe part,
a housing body which mechanically connects the first and second leadframe parts to one another,
wherein
the first leadframe part has a mounting region for attaching the semiconductor chip and/or for attaching an electrical connecting means and has an edge region on a lateral edge of the housing,
the first leadframe part has a trench between the mounting region and the edge region, and
the trench is located on an outer side of the first leadframe part and the outer side is configured for mounting the housing, and
the trench is located on an outer side of the first leadframe part and the outer side is configured for mounting the housing, and the mounting region and the edge region extend to the outer side.

In the housing described herein, in particular solder control structures are mechanically decoupled from the mounting region. This reduces the risk of delamination of the housing body from the first leadframe part in the edge region.

The housing can be a so-called Quad Flat No Leads component, or QFN component for short.

The AEC Q102 #3 standard stipulates that no delamination of metal pads to which bonding wires are attached is permitted. This standard refers in particular to LED components that contain an IC and are intended for the automotive sector.

With the concept described herein for the leadframe parts, the forces and stresses in the housing can be reduced to such an extent that the surrounding housing plastic of the housing body sticks to the metal of the leadframe parts. Studies show that the plastic flakes off particularly easily on the top side of etched solder control structures, that is, at the edge region. One reason for this is probably that large leadframe parts transfer a large leverage effect to the solder control structures. With the concept described here, the affected solder control structures are mechanically decoupled from the large mounting region, but remain thermally and electrically connected.

In the narrow connection in the area between the mounting region and the edge region, the material thickness is preferably halved along a straight line, for example, by removing material from the bottom side of the component—that is, the trench is formed. Viewed in longitudinal section and in plan view, the trench is preferably in the area of a cavity and not in the area of a housing plastic wall. The trench is thus located in particular below a cavity base, close to the cavity wall.

The continuous reduction in material thickness in the area of the trench creates a kind of joint between the large mounting region and the edge region with the solder control structures. The trench should run in a straight line to achieve maximum effect. The material is removed from the outer side so that the remaining metal connection is closer to the neutral zone of an imaginary bending line.

If standard QFN components are stored at temperature and humidity, for example, according to a Temperature and Humidity Storage, THS for short, for 168 hours at 60° C. and 85% relative humidity, and then soldered onto an FR4 PCB, for example, according to a Resistance To Soldering Heat Test, RTSH test for short, then delamination between a cavity potting material and the metal leadframe, also known as the leadframe, often spreads over a large area. According to the AEC Q102 #3 standard, all delaminations between the cavity encapsulation material and metal pads are to be excluded for such LED components with IC if these pads are wirebond pads.

Delamination occurs in particular due to the so-called popcorn effect. This means that during temperature and humidity storage, a film of moisture forms in gaps between the leadframe parts and the housing body. During subsequent soldering according to RTSH, maximum temperature 260° C., this moisture evaporates abruptly and takes up a much larger volume in the form of hot water vapor. Viewed in longitudinal cross-section, the explosive water vapor shoots out of the gaps and squeezes directly between the cavity potting material and the leadframe. The cavity potting material is a silicone or an epoxy, for example. This results in large-area delamination between the cavity potting material and metal surfaces.

This means that the damage mechanism described is caused in particular by the gaps between the housing body and the metal leadframe. On the one hand, the adhesion between the housing body, which is based on an epoxy potting material or a silicone potting material, for example, and metal is relatively low, and on the other hand, the metal leadframe is quite rigid. In addition, the difference in the thermal expansion coefficients between the metal and the housing body leads to severe bending in the panel composite, which is why the panel composite is usually pressed flat several times by machine.

The housing described here combines in particular several approaches:
a) In general, the aim is to switch from so-called pre-plating to post-plating. For this purpose, the leadframe, especially the copper leadframe, is first provided with the housing body and only then coated with a metallization such as NiPdAu. Pre-plating is done in reverse. The housing body generally adheres better to copper than to a metallization such as NiPdAu.
b) The solder control structures can be omitted in the area of the second leadframe parts. This makes the second leadframe parts better anchored in the housing body and also more flexible. This can reduce gap formation in the areas on the second leadframe part.
c) However, the trenches and the solder control structures, also known as SCS for short or as solder control points, are present on the preferably larger first leadframe parts. Thus, the trenches incorporate a predetermined buckling point in the leadframe to protect the SCS area from forces that cause delamination.

As the housing body is mechanically more stable in the area of full material thickness, that is, outside a cavity, than in the area of a cavity, the housing plastic tends to deform more in the area of the cavity when the panel is bent. The metal leadframe is similarly rigid and would essentially retain its shape without the trench. The leadframe can buckle due to the trench. This prevents half-sided delamination, starting on the inner side of the edge region. This means that the housing described here is based, among other things, on the idea of creating an additional buckling point outside the area of the SCS in the form of the trench, at which the leadframe is allowed to buckle, which means that the adhesion to the housing body no longer has to break under load.

This buckling point is preferably directly at or close to the cavity wall. It is preferred to create this kink point within the large, first cavity. However, it may be useful to create a kink point on both sides of the SCS areas, that is, also on the second leadframe part.

With the housing described herein, in particular the following effects can be achieved:
The solder control structures, SCS, can be left in place and do not need to be removed to solve the delamination problem. In combination with other measures, such as post-plating and/or adapted shape of the second leadframe parts, this is an efficient measure to reduce the risk of delamination between the housing body and the metal at a significant point, in particular to achieve conformity with the AEC Q102 #3 standard.
Another effect is that such delaminations above the SCS represent undesirable entry paths on the inner side for gases, for example H₂S, which are preferably avoided to achieve higher corrosion resistance.

According to at least one embodiment, the trench extends continuously between the mounting region and the edge region. In particular, this means that no point of the leadframe between the mounting region and the edge region is thicker than in the area of a valley bottom of the trench.

Preferably, the trench extends along a straight line.

According to at least one embodiment, the trench is interrupted by one or more transverse bars. In particular, there is exactly one transverse bar or there are exactly two transverse bars. Such transverse bars make it possible to control the material flow of the housing body during its manufacture.

According to at least one embodiment, the at least one transverse bar is just as thick as the mounting region and/or the edge region. In the area of the transverse bars, the first leadframe part therefore preferably has the full thickness.

According to at least one embodiment, a width of the transverse bar or the sum of the widths of all transverse bars along the trench taken together is at most 40% or at most 30% or at most 20% of a total length of the trench including the at least one transverse bar. This means that the transverse bars are relatively narrow in relation to the total length.

According to at least one embodiment, the trench is partially or completely filled by the housing body. In particular in the case where two of the transverse bars are present, the trench can be free of the housing body.

According to at least one embodiment, the housing body forms a first cavity. In the first cavity, an inner side of the first leadframe part, which is set up for attaching the semiconductor chip, for example, is free from the housing body. It is possible that the first cavity is limited to the first leadframe part, seen in plan view of the inner side. In this case, there may be a second cavity that exposes the inner side of the second leadframe part. Alternatively, the first cavity extends over the first and the second leadframe parts.

According to at least one embodiment, the edge region is partially or completely covered by a cavity wall of the first cavity, seen in plan view on the inner side. This means that the first cavity does not extend as far as the edge region, but in particular only as far as the trench.

According to at least one embodiment, the trench is partially or completely inside the first cavity when viewed on the inner side.

According to at least one embodiment, the trench, seen in plan view on the inner side and towards the edge region, borders on the cavity wall of the first cavity. In particular, a boundary line of the cavity wall, in the direction from an outer side wall of the housing at the edge region towards the mounting region, and a longitudinal edge of the trench facing the edge region lie congruently one above the other, as seen in plan view of the inner side. This applies, for example, with a tolerance of at most 20 μm or of at most 50 μm or of at most 0.1 mm, alternatively or additionally with a tolerance of at most 10% or of at most 25% or of at most 50% of a width of the trench.

According to at least one embodiment, the cavity wall of the first cavity and the trench overlap partially or completely, preferably only to a small extent of, for example, at most 40% or at most 20% of a base area of the trench, seen in plan view on the inner side.

According to at least one embodiment, when viewed on the inner side, all ends of the trench lie within the first cavity. In other words, the trench ends inside the first cavity.

According to at least one embodiment, the edge region comprises one or more solder control points. It is possible that the at least one solder control point is provided with a metal coating. In particular, such a metal coating of the solder control point is located on a surface of the solder control point extending transversely to the outer side. This transverse surface may lie in the plane of the associated outer side wall of the housing or be set back relative to the outer side wall. This metal coating is preferably the same metal coating as on the outer side of the mounting region and of regions of the edge region that lie in the outer side.

This means that the metal coating is applied to the first leadframe part at least in the area of the solder control point and preferably also in the mounting region.

According to at least one embodiment, the edge region comprises several of the solder control points. It is possible that there is exactly one solder control point per edge region or that one edge region comprises several or even all of the solder control points of the leadframe part in question. If there are several edge regions with at least one solder control point, these edge regions can all have the same design or can also differ from one another.

According to at least one embodiment, at least two of the solder control points are divided from each other in the direction transverse to the trench by a slot through the first leadframe part. This means that the solder control points in question can be adjacent to each other and have the same design. In particular in the direction parallel to the trench, there is then no continuous material connection between these solder control points within the first leadframe part due to the slot.

According to at least one embodiment, the slot partially or completely cuts through the trench. This means that, due to the slot, there is no longer any material of the first leadframe part in the direction parallel to the trench and in the area of the trench, at least in places. It is possible that the slot divides the trench into two partial trenches.

According to at least one embodiment, the slot widens in places in the direction away from the assigned solder control points and in particular in the direction towards the trench. It is possible that the slot remains the same width in a first plane and only widens in a second plane. The second plane is, for example, the half-etched side of the first leadframe part, in which the trench is also formed.

According to at least one embodiment, the trench is semicircular or polygonal, such as quadrangular, in places or along the entire longitudinal axis when viewed in cross-section, in particular when viewed perpendicular to a longitudinal axis of the trench. Quadrangular means, for example, that the trench has a square or trapezoidal cross-sectional area.

According to at least one embodiment, a trench depth is at least 35% or at least 40% or at least 45% of a total thickness of the first leadframe part. Alternatively or additionally, the trench depth is at most 65% or at most 50% of the total thickness.

According to at least one embodiment, the total thickness of the first leadframe part is at least 100 μm or at least 140 μm. Alternatively or additionally, the total thickness is at most 250 μm or at most 210 μm.

According to at least one embodiment, a width of the trench is at least 50% or at least 80% of the total thickness of the first leadframe part. Alternatively or additionally, the width is at most 300% or at most 200% or at most 150% of the total thickness. For example, the width of the trench is between 0.1 mm and 0.3 mm inclusive.

According to at least one embodiment, the first leadframe part is larger than the second leadframe part. For example, the sizes of the leadframe parts differ by at least a factor of 1.2 or by at least a factor of 1.5 or by at least a factor of 2 and/or by at most a factor of 10. In particular, the size refers to a base area of the leadframe parts as viewed on the inner side in plan view.

According to at least one embodiment, the second leadframe part comprises a mounting region and/or one or more further solder control points. The mounting region of the second leadframe part is provided, for example, for an ESD protection chip, a drive IC and/or a bonding wire connection.

According to at least one embodiment, the second leadframe part is of constant thickness between the further solder control point and the mounting region. In other words, the second leadframe part then does not comprise an edge region offset from the mounting region, but the mounting region extends to the edge and comprises the at least one further solder control point.

According to at least one embodiment, there is at least one further trench between the at least one further solder control point and the mounting region of the second leadframe part. That is, due to said trench, the second leadframe part is divided into the mounting region and the at least one edge region.

The explanations regarding the trench, the solder control point and the edge region for the first leadframe part apply in the same way to the further solder control point and the further trench of the second leadframe part.

According to at least one embodiment, the first leadframe part comprises a plurality of the edge regions, each of which is separated from the mounting region of the first leadframe part by a trench.

In addition, a leadframe unit is provided for a housing as described in connection with one or more of the above embodiments. Features of the leadframe unit are therefore also disclosed for the housing and vice versa.

In at least one embodiment, the leadframe unit is provided for a housing, and comprises a first leadframe part and a second leadframe part, for an optoelectronic semiconductor chip, wherein
the first leadframe part has a mounting region for attaching a semiconductor chip and/or for attaching an electrical connecting means and has an edge region at a lateral edge of the leadframe unit,
the first leadframe part has a trench between the mounting region and the edge region, and
the trench is located on an outer side of the first leadframe part and the outer side is configured for flat solder mounting of the mounting region and the edge region.

In addition, an optoelectronic semiconductor component with a housing as described in connection with one or more of the above embodiments is disclosed. Features of the optoelectronic semiconductor component are therefore also disclosed for the housing and vice versa.

In at least one embodiment, the optoelectronic semiconductor component comprises the housing and at least one optoelectronic semiconductor chip mounted in the housing.

In addition, a method of manufacturing a housing as described in connection with one or more of the above embodiments is disclosed. Features of the housing are therefore also disclosed for the method and vice versa.

In at least one embodiment, the method comprises the following steps, in particular in the order given:
providing a metallic semi-finished product,
producing a leadframe composite with a plurality of the leadframe units from the semi-finished product, in particular by means of a two-stage etching process, each etching step being carried out from a main side of the semi-finished product,
producing a housing base body on the leadframe composite,
optionally attaching and electrically contacting the at least one optoelectronic semiconductor chip in the housing,
optionally filling the cavities with a filling, and
singulation to form the housings and/or optoelectronic semiconductor components.

### BRIEF DESCRIPTION OF THE DRAWINGS

In the following, a housing described herein, an optoelectronic semiconductor component described herein, a method described herein and a leadframe unit described herein are explained in more detail with reference to the drawing by means of examples. Identical reference signs indicate the same elements in the individual figures. However, no references to scale are shown; rather, individual elements may be shown in exaggerated size for better understanding.

In the figures:

FIG. 1 is a schematic perspective view of an exemplary embodiment of a leadframe unit described herein for a housing described herein;

FIG. 2 is a schematic perspective sectional view of an exemplary embodiment of a housing described herein with the leadframe unit of FIG. 1;

FIG. 3 is a schematic perspective view of the housing of FIG. 2;

FIGS. 4 and 5 are schematic top views of main sides of the leadframe unit of FIG. 1;

FIG. 6 is a schematic sectional view of an exemplary embodiment of an optoelectronic semiconductor component described herein with the housing of FIG. 2;

FIG. 7 is a schematic sectional view of a process step of an exemplary embodiment of a process for manufacturing a housing described herein;

FIG. 8 is a schematic perspective view of a modification of the leadframe unit of FIG. 1;

FIG. 9 is a schematic perspective view of a modification of the housing of FIG. 2;

FIG. 10 is a schematic perspective view of an exemplary embodiment of a leadframe unit described herein for a housing described herein;

FIG. 11 is a schematic sectional view of an exemplary embodiment of a housing described herein with the leadframe unit of FIG. 10;

FIG. 12 is a schematic perspective view of an exemplary embodiment of a leadframe unit described herein for a housing described herein;

FIG. 13 is a schematic sectional view of an exemplary embodiment of a housing described herein with the leadframe unit of FIG. 12;

FIG. 14 is a schematic perspective view of a modification of the leadframe unit of FIG. 12;

FIG. 15 is a schematic perspective view of an exemplary embodiment of a leadframe unit described herein for a housing described herein;

FIG. 16 is a schematic perspective sectional view of an exemplary embodiment of a housing described herein with the leadframe unit of FIG. 15;

FIG. 17 is a schematic perspective view of a modification of the leadframe unit of FIG. 15; and

FIGS. 18 and 19 are schematic perspective views of exemplary embodiments of leadframe units described herein for housing described herein.

### DETAILED DESCRIPTION OF ILLUSTRATIVE EMBODIMENTS

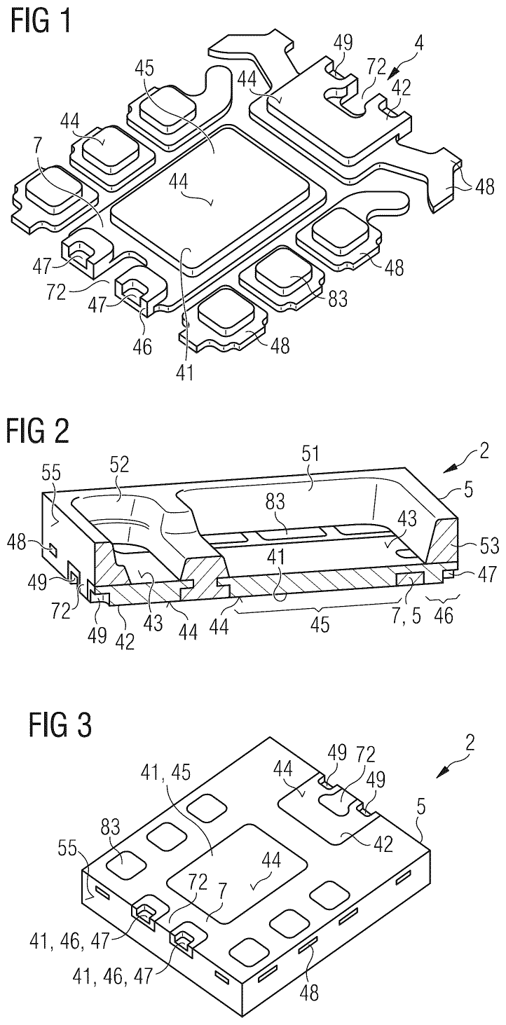

FIGS. 1, 4 and 5 show an example of a leadframe unit 4. The leadframe unit 4 comprises a first leadframe part 41 and a second, smaller leadframe part 42. Optionally, one or more further leadframe parts 83 are present, which may be smaller than the second leadframe part 42. The leadframe parts 41, 42, 83 are made, for example, from a sheet of semi-finished material, such as sheet copper.

Many of these leadframe units 4 can be combined in a leadframe composite, not shown. Neighboring leadframe units 4 are then mechanically connected to each other via tie bars 48 until they are separated.

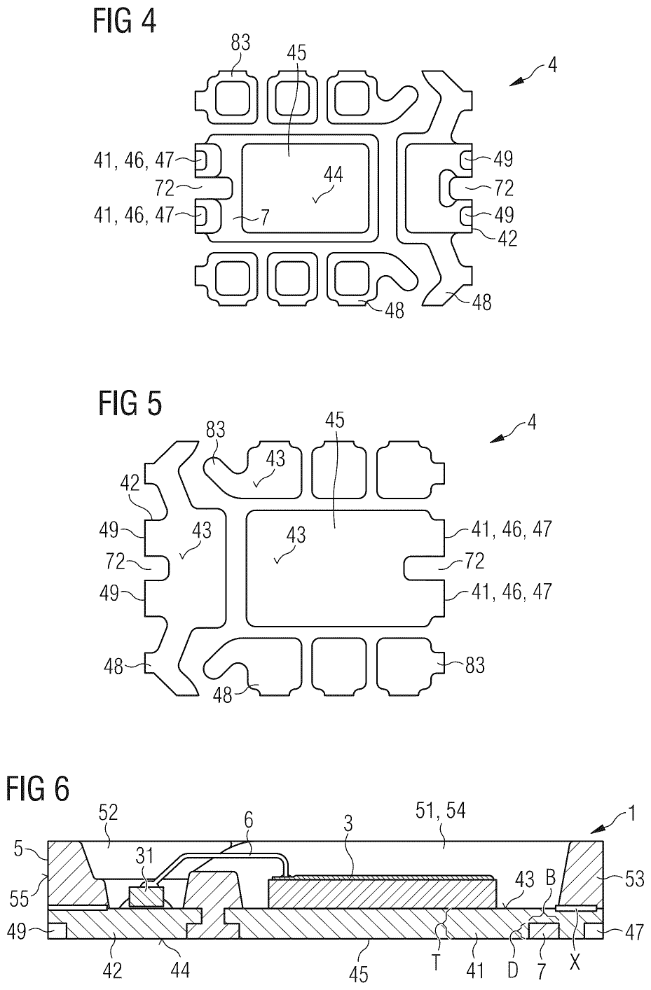

The leadframe parts 41, 42, 83 are etched from the semi-finished product from two main sides by means of two-stage half etching and are thus made of the same material and of the same thickness. The half etching is, for example, more extensive from an outer side 44 than from an opposite inner side 43, see in particular FIGS. 4 and 5. Thus, the inner side 43 has a larger surface area than the outer side 44.

The outer side 44 is set up for surface mounting of a later housing 2 with the leadframe unit 4, see also FIGS. 2 and 3. The inner side 43 of the first leadframe part 41 is configured in a mounting region 45 for attaching an optoelectronic semiconductor chip, such as an LED chip. Accordingly, the second leadframe part 42 is used on the inner side 42 in particular for attaching a bonding wire and/or an ESD protection diode. In the respective mounting region 45, the leadframe parts 41, 42 have their full thickness.

The first leadframe part 41 also has an edge region 46 which borders on an outer outline of the leadframe unit 4 and which is thus exposed in places on an outer side wall of the housing 2, see FIG. 3. The edge region 46 has two solder control points 47, which are formed by pockets from the outer side 44. The solder control points 47 comprise surfaces oriented transversely to the outer side 44, which are set up to be wetted by a solder during assembly of the housing 2.

In deviation from the representation in the figures, it is not absolutely necessary that the solder control points 47 comprise the pockets. It is equally possible for the solder control points 47 to be formed only by surfaces on the outer side walls that are configured for being wetted with the solder. This also applies in all other examples.

Except for an area with the optional pockets, the edge region 46 has the full thickness of the leadframe part 41. An area of reduced thickness is located between the edge region 46 and the mounting region 45 of the first leadframe part 41. This area represents a trench 7, which preferably divides the edge region 46 from the mounting region 45 in a straight line without interruption. Viewed in cross-section, the trench 7 is approximately rectangular.

The smaller second leadframe part 42 is free of such a trench, so that the second leadframe part 42 has its full thickness all the way to the outer outline.

Optionally, a plurality of the solder control points 47 are each located on the first and/or on the second leadframe part 41, 42, for example, two solder control points 47 each. As a further option, it is possible that the solder control points 47 are each separated from one another by a slot 72. It is possible that the slot 72 widens at least on the outer side 44 in the direction away from the solder control points 47, see the second leadframe part 42. Alternatively, the slot 72 can be of constant width, see the first leadframe part 41.

It is possible that the slot 72 on the first leadframe part 41 extends into the trench 7. In this case, however, the slot 72 only partially penetrates the trench 7 in a direction perpendicular to a longitudinal axis of the trench, see FIGS. 1 and 4.

FIG. 2 shows that the housing 2 also comprises a housing body 5 in addition to the leadframe unit 4. The housing 2, which according to FIG. 2 does not yet comprise a semiconductor chip, can still be present in a housing composite, not shown, so that the outer side walls 55 are only formed when the housing composite is divided into the individual housings 2 or semiconductor components.

The housing body 5 forms two cavities 51, 52, wherein each of the leadframe parts 41, 42 and optionally the further leadframe parts 83 are exposed in places due to the cavities 51, 52, so that the inner sides 43 are accessible. The cavities 51, 52 are preferably surrounded all around by a cavity wall 53. It is possible that the cavity wall 53 between the cavities 51, 52 is lower than at the outer side walls 55.

For example, the solder control points 47 are each completely covered by the associated cavity wall 53. It is possible that the slots 72 are only partially covered by the respective cavity wall 53. The trench 7, which may be completely or substantially completely filled by the housing body 5, is located at the cavity wall 53. For example, an inner edge of the cavity wall 53 on the inner side 43 and an outer side wall of the trench 7, which is located closer to the associated side wall 55, lie in a common plane perpendicular to the inner side 43. This applies, for example, with a tolerance of at most 0.2 mm.

This position of the trench 7 makes it possible for the relatively large first leadframe part 41 to bend under tension, that is, to exhibit a slight kink along the trench 7. As a result, the edge region 46 adheres better to the cavity wall 53 than in the case of a constantly thick first leadframe part 41.

This subdivision of the first leadframe part 41 into the edge region 46 with the optional solder control points 47 and into the mounting region 45 due to the trench 7 can be seen in particular in FIG. 3: The housing body 5 extends continuously between the edge region 46 and the mounting region 45.

The illustration in FIGS. 1 to 5 is to scale. For example, this is a 2720 component.

FIG. 6 shows an example of an optoelectronic semiconductor component 1 comprising the housing 2 of FIGS. 2 and 3. The optoelectronic semiconductor chip 3 and the further semiconductor chip 31, such as an ESD protection chip, are soldered in the cavities 51, 52. An electrical connection is made via electrical connecting means 6, such as bonding wires.

The trench 7 has a trench depth D which is, for example, between 40% and 60% of a total thickness T of the leadframe parts 41, 42, 83. In order to ensure a sufficient decrease in the bending stiffness of the first leadframe part 41 in the area of the trench 7, the trench 7 preferably has a width B such that: 0.8 T≤B≤2 T or 1.2 T≤B≤1.6 T. This can also apply in all other examples.

FIG. 6 shows as a further option that the cavities 51, 52 can be partially or completely filled with a filling 54. The filling 54 is, for example, a silicone compound which may contain at least one admixture, such as light scattering particles, a phosphor and/or an optical filter material.

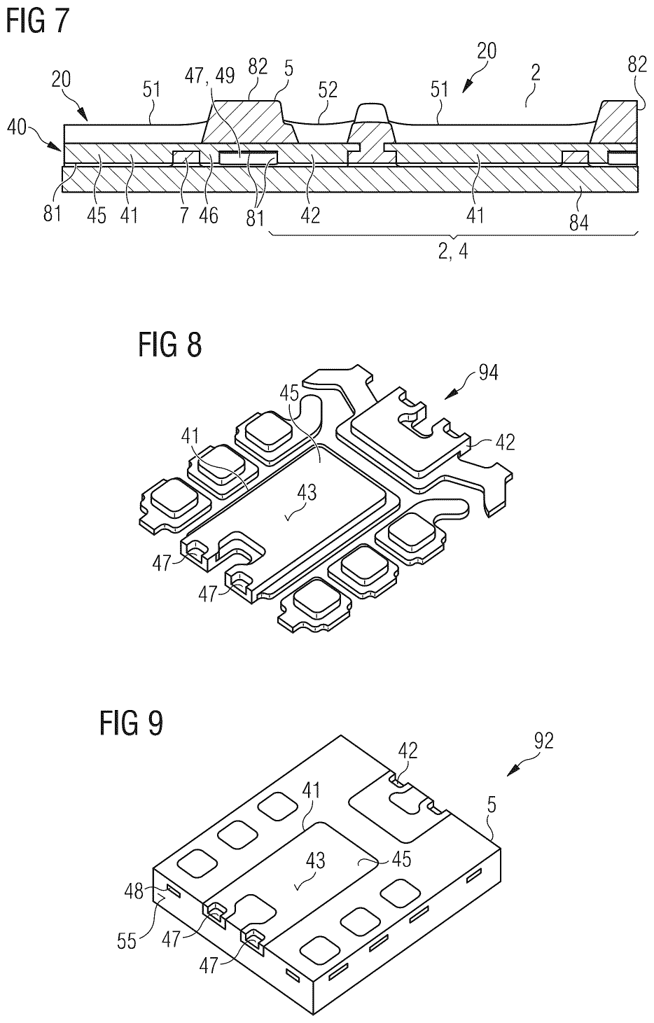

A manufacturing process for the housing 2 is illustrated schematically in connection with FIG. 7. The housing 2 is constructed, for example, as described in connection with FIGS. 1 to 5.

The leadframe composite 40 with a plurality of leadframe units 4, each half-etched from its two main sides, is located on a carrier 84, for example, a film for film-assisted molding, or FAM for short. The housing composite 20 is produced on the carrier 84. Adjacent units are subsequently cut along separation lines 82, resulting in the individual components and the side walls 55. Preferably, the semiconductor chips 3, 31, the electrical connecting means 6 and the optional filling 54 are already placed before cutting.

Furthermore, FIG. 7 illustrates that only the areas of the outer side 44 not covered by the housing body 5 are covered by a metal coating 81, such as NiPdAu. This metal coating 81 also covers all exposed areas of the pockets forming the solder control points 47. Such a metal coating 81 can be formed by applying the metal coating 81 after the housing body 5 has been created.

FIG. 8 shows a modification 94 of the leadframe unit from FIG. 1 and FIG. 9 shows a modification 92 of the housing from FIG. 2, which do not have a trench on the first leadframe part 41. As a result, in a danger area X, see FIG. 6, there is an increased risk that the first leadframe part 41 cannot sufficiently compensate for thermomechanical stresses, in particular during soldering, and becomes detached from the housing body 5 in the area of the cavity wall 53. The risk of such delamination is significantly reduced by the trenches 7 in the leadframe units 4 described here.

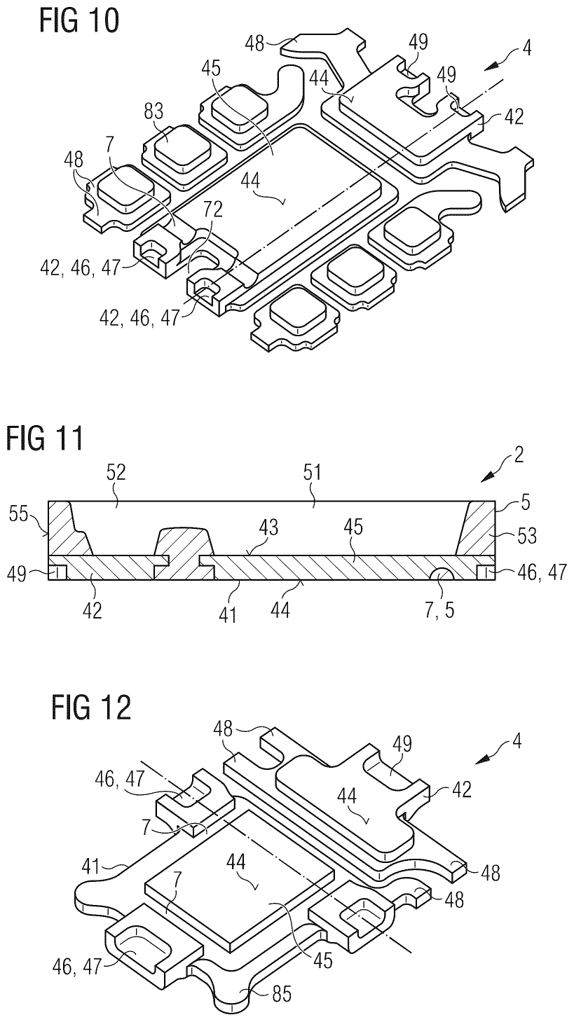

FIG. 10 illustrates another example of the leadframe unit 4. The associated housing 2 can be seen in FIG. 11; the section line for the section of FIG. 11 is shown in FIG. 10 as a dash-dot line. In contrast to the design of FIGS. 1 to 5, the trench 7 is semicircular and not angular when viewed in cross-section.

As a further option, it is possible for the slot 72 in the first leadframe part 41 to completely penetrate the trench 7 on the outer side 44. As a result, there are two partial trenches on the outer side 44 that run in extension of one another. The slots 72 of both leadframe parts 41, 42 can thus have the same shape, except for the trench 7.

These designs of the trench 7 and the slot 72 are correspondingly also possible in all other examples.

The illustration in FIGS. 10 and 11 is to scale. For example, this is a 2720 component.

In all other respects, the comments on FIGS. 1 to 7 apply in the same way to FIGS. 10 and 11, and vice versa.

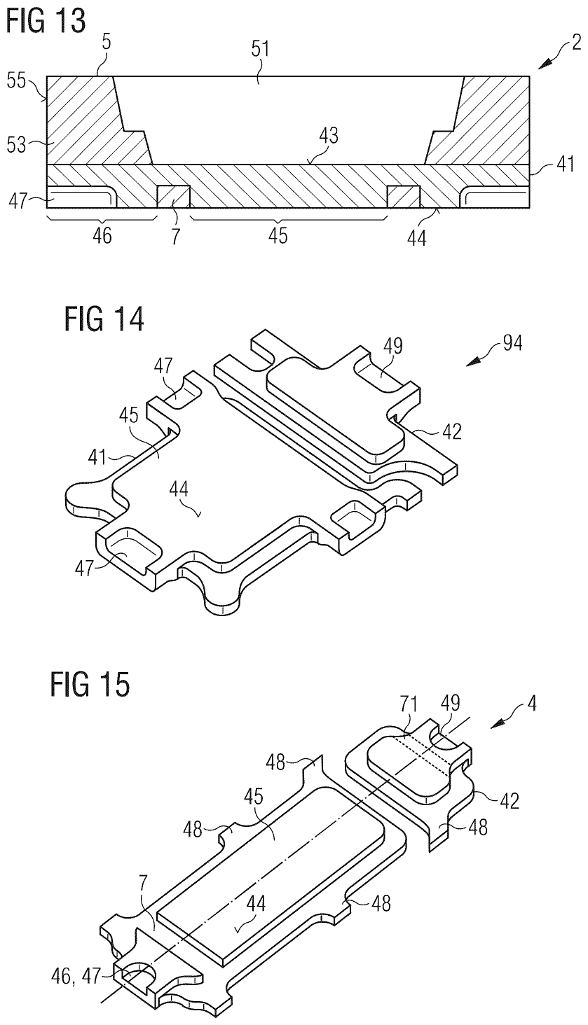

FIG. 12 illustrates another example of the leadframe unit 4. The associated housing 2 can be seen in FIG. 13; the section line for the section of FIG. 13 is shown in FIG. 12 as a dash-dot line.

The first leadframe part 41 has several of the edge regions 46, each with one of the solder control points 47. Thus, the solder control points 47 of the first leadframe part 41 are present on three side walls of the cubic housing 2, and the further solder control point 49 of the second leadframe part 42 is located on the fourth side wall.

Thus, three of the trenches 7 are present in the first leadframe part 41. The second leadframe part 42 can be free of a trench.

Optionally, as in all other examples, the mounting region 45 of the first leadframe part 41 may be provided with corner extensions 85 in order to increase the stability of the housing 2.

The illustration in FIGS. 12 and 13 is to scale. For example, this is a 2720 component.

In all other respects, the explanations to FIGS. 1 to 11 apply in the same way to FIGS. 12 and 13, and vice versa.

FIG. 14 shows the modification 94, which corresponds to the example of FIG. 12 except for the missing trench.

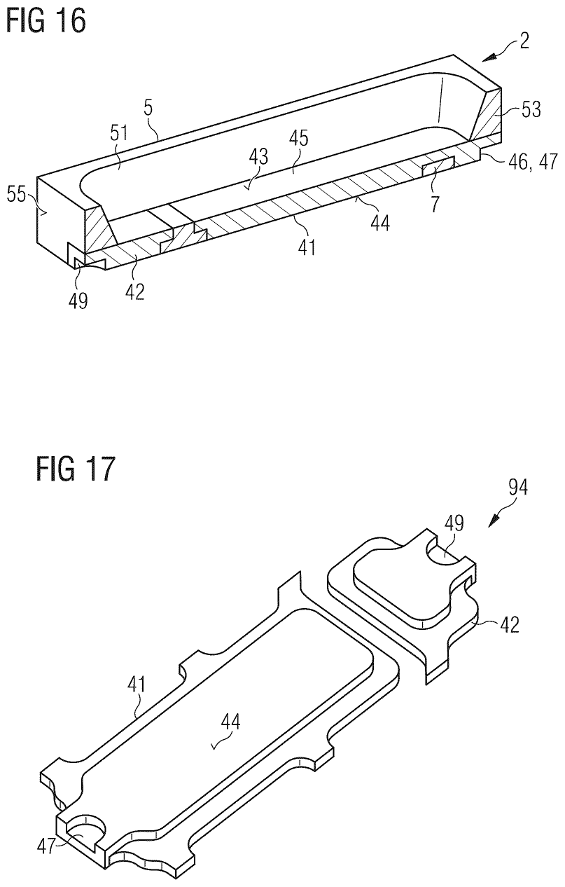

FIG. 15 illustrates another example of the leadframe unit 4. The associated housing 2 is shown in FIG. 16; the section line for the section of FIG. 16 is shown in FIG. 15 as a dash-dot line.

The mounting region 45 is elongated and the solder control points 47, 49 are located on the short sides of the leadframe unit 4. The first leadframe part 41 again has the trench 7.

In FIG. 15, it is shown as a dashed line that the second leadframe part 42 can also have a further trench 71 in order to place the further solder control point 49 in an edge region. Such a further trench 71, to which the remarks on the trench 7 apply accordingly, may also be present in all other examples, in particular in the designs of FIGS. 1, 10, 12, 18 and 19.

The illustration in FIGS. 15 and 16 is to scale. For example, this is a 4014 component.

In all other respects, the explanations in FIGS. 1 to 14 apply in the same way to FIGS. 15 and 16, and vice versa.

FIG. 17 shows the modification 94, which corresponds to the example in FIG. 15 except for the missing trench.

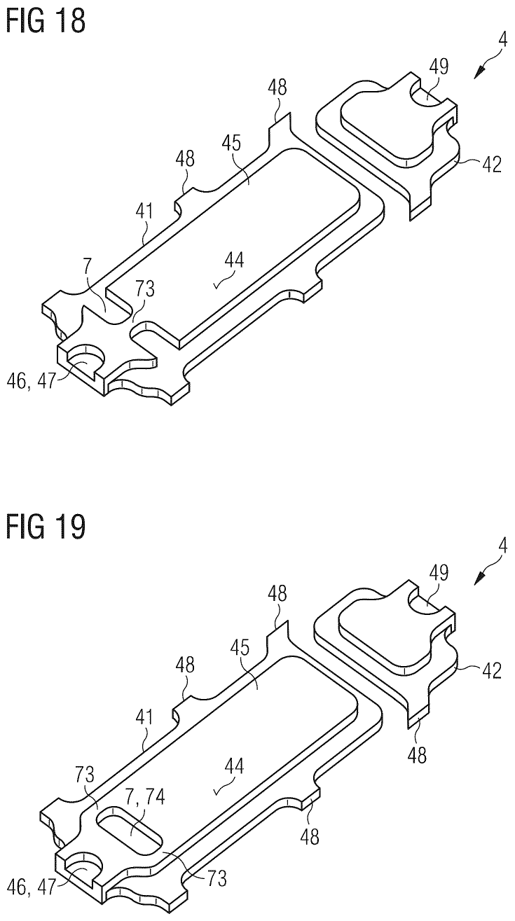

The examples in FIGS. 18 and 19 are based on the example in FIG. 15 and it is shown that the trenches 7 do not necessarily have to be continuous.

Thus, there is a central transverse bar 73 in the trench 7 of FIG. 18, which extends with the full thickness of the first leadframe part 41 through the trench 7. In the direction parallel to the longitudinal axis of the trench 7, however, the transverse bar 73 is narrow, so that the buckling capacity of the first leadframe part 41 is not significantly reduced by the transverse bar 73.

In contrast, the trench 7 of FIG. 19 is provided with two of the transverse bars 73. The transverse bars 73 are located at the ends of the trench 7 and thus close the trench 7, resulting in a pocket 74. Due to the two transverse bars 73, the pocket 74 can remain free of the housing body 5.

Such transverse bars 73, as illustrated in FIGS. 18 and 19, may also be present in all other examples. If further trenches 71 are present on the second leadframe part 42, such transverse bars 73 may also be used at the further trenches 71.

The illustration in FIGS. 15 and 16 is to scale. These are, for example, 4014 components.

In all other respects, the comments on FIGS. 1 to 16 apply in the same way to FIGS. 17 and 18, and vice versa.

The components shown in the figures preferably follow one another in the order indicated, in particular directly one after the other, unless otherwise described. Components not touching each other in the figures preferably have a distance between them. If lines are drawn parallel to each other, the associated surfaces are preferably also aligned parallel to each other. Furthermore, the relative positions of the drawn components to each other are correctly shown in the figures, unless otherwise specified.

The invention described herein is not limited by the description based on the embodiments. Rather, the invention includes any new feature as well as any combination of features, which includes in particular any combination of features in the patent claims, even if this feature or combination itself is not explicitly stated in the patent claims or embodiments.

1-20. (canceled)

21. A housing comprising:
a first leadframe part;
a second leadframe part; and
a housing body mechanically connecting the first and second leadframe parts to one another,
wherein the first leadframe part has a mounting region configured for attaching a semiconductor chip and/or for attaching an electrical connection, and an edge region at a lateral edge of the housing,
wherein the first leadframe part has a trench between the mounting region and the edge region,
wherein the trench is located on an outer side of the first leadframe part and the outer side is configured for mounting the housing,
wherein the mounting region and the edge region extend as far as the outer side,
wherein the housing body forms a first cavity and, in the first cavity, an inner side of the first leadframe part, which is configured for mounting the semiconductor chip, is free from the housing body,
wherein the edge region is at least partially covered by a cavity wall of the first cavity, as seen in plan view of the inner side, and
wherein, as seen in plan view of the inner side, all ends of the trench lie within the first cavity.

22. The housing according to claim 21, wherein the trench extends continuously between the mounting region and the edge region.

23. The housing according to claim 21,
wherein the trench is interrupted by at least one transverse bar and the transverse bar is as thick as the mounting region and the edge region, and
wherein a width of the transverse bar or a sum of the widths of all transverse bars along the trench is at most 40% of a total length of the trench.

24. The housing according to claim 23, wherein the trench is partially filled by the housing body.

25. The housing according to claim 21, wherein the housing body further comprises a second cavity such that an inner side of the second leadframe part is exposed.

26. The housing according to claim 21, wherein the trench is located completely within the first cavity as seen in plan view of the inner side.

27. The housing according to claim 21, wherein, seen in plan view on the inner side and towards the edge region, the trench is adjacent to the cavity wall of the first cavity.

28. The housing according to claim 21,
wherein the edge region comprises a solder control point, and
wherein the solder control point is freely accessible from outer side walls of the housing.

29. The housing according to claim 28, further comprising a metal coating arranged at the first leadframe part in a region of the solder control point.

30. The housing according to claim 28,
wherein the edge region comprises two of the solder control points, and
wherein the two solder control points are divided from each other in a direction transverse to the trench by a slot through the first leadframe part.

31. The housing according to claim 30, wherein the slot partially or completely cuts through the trench.

32. The housing according to claim 30, wherein the slot widens in places in a direction away from the two solder control points and towards the trench.

33. The housing according to claim 21, wherein the trench is semicircular or quadrangular when viewed in cross-section.

34. The housing according to claim 21,
wherein a depth of the trench is at least 35% and at most 65% of a total thickness of the first leadframe part, and
wherein the total thickness is between 100 μm and 250 μm, inclusive.

35. The housing according to claim 34,
wherein a width of the trench is at least 50% and at most 200% of the total thickness of the first leadframe part.

36. The housing according to claim 21,
wherein the first leadframe part is larger than the second leadframe part, and
wherein the second leadframe part comprises a mounting region and a further solder control point.

37. The housing according to claim 36, wherein the second leadframe part has a constant thickness between the further solder control point and its mounting region.

38. The housing according to claim 36, further comprising a further trench located between the further solder control point and the mounting region of the second leadframe part.

39. The housing according to claim 21, wherein the housing comprises a plurality of the edge regions and a plurality of the trenches, each edge region being separated from the mounting region of the first leadframe part by one of the trenches.

40. A leadframe unit comprising:
a first leadframe part; and
a second leadframe part,
wherein the first leadframe part has a mounting region configured for attaching a semiconductor chip and/or for attaching an electrical connecting connection, and an edge region at a lateral edge of the leadframe unit,
wherein the first leadframe part has a trench between the mounting region and the edge region, and
wherein the trench is located on an outer side of the first leadframe part and the outer side is configured for a planar solder mounting of the mounting region and the edge region.
